(19) United States
(12) Patent Application Publication
(10) Pub. No.: US 2025/0068800 A1
(43) Pub. Date: Feb. 27, 2025

(54) PRE-DEPLOYMENT USER JOURNEY EVALUATION

(71) Applicant: ADOBE INC., San Jose, CA (US)

(72) Inventors: Lei Zhang, Fremont, CA (US); Jun He, Fremont, CA (US); Zhenyu Yan, Cupertino, CA (US); Roger K. Brooks, Palo Alto, CA (US)

(21) Appl. No.: 18/455,005

(22) Filed: Aug. 24, 2023

(51) Int. Cl. G06F 30/27

(52) U.S. Cl. CPC G06F 30/27

(57) ABSTRACT

Systems and methods for pre-deployment user journey evaluation are described. Embodiments are configured to obtain a user journey including a plurality of touchpoints; generate a simulation agent including a plurality of attributes; generate a probability score for the simulation agent for each of the plurality of touchpoints based on the plurality of attributes using a machine learning model; perform a simulation of the user journey based on the probability score; and generate a text describing the user journey based on the simulation.

### BACKGROUND

The following relates generally to data processing, and more specifically to user journey evaluation. A user journey is a model used to organize the various interactions and experiences an individual has with a brand or organization, from initial contact to final interaction. A user journey can encompass several stages like discovery, consideration, decision-making, purchasing, and post-purchase engagement. In some cases, during the process of creating user journeys, creators construct a graph with multiple ‘touchpoints’, which are individual instances of interaction between the user and the system, such as an email or a push notification. Once a journey has been deployed, creators can analyze data gathered at each touchpoint to understand user behavior, and refine their strategies for subsequent user. However, this “trial-and-error” approach for can be costly and time-consuming. There is a need in the art for systems and methods to gather metrics on a user journey and identify potential optimizations before deployment.

### SUMMARY

Systems and methods for pre-deployment user journey evaluation are described. Embodiments include a journey evaluation apparatus configured to process a user journey. For example, a creator or designer produces an initial user journey using software, and then input the initial user journey into the journey evaluation apparatus. Embodiments of the apparatus generate one or more simulation agents, where each simulation agent has a plurality of attributes that are sampled from a distribution of historical data. In some cases, the attributes are sampled so as to simulate a user that will take the user journey. Embodiments of the apparatus include a machine learning model that takes the attribute as input, and then predicts an action of the simulation agent in the user journey. In some cases, the action corresponds to a click or open action at each of various touchpoints included in the user journey. Embodiments are configured to compute metrics and identify insights about the user journey such as bottlenecks based on the simulated actions. In some cases, embodiments further suggest improvements to the user journey.

A method, apparatus, non-transitory computer readable medium, and system for user journey evaluation are described. One or more aspects of the method, apparatus, non-transitory computer readable medium, and system include obtaining, through a user interface, a user journey including a plurality of touchpoints; generating, using an agent generator component, a simulation agent including a plurality of attributes; generating, using a machine learning model, a probability score for the simulation agent for each of the plurality of touchpoints based on the plurality of attributes; performing, using a simulator component, a simulation of the user journey based on the probability score; and generating, using a journey evaluation apparatus, a text describing the user journey based on the simulation.

An apparatus, system, and method for user journey evaluation are described. One or more aspects of the apparatus, system, and method include a non-transitory computer readable medium storing code, the code comprising instructions executable by a processor to: obtain a user journey including a plurality of touchpoints; generate a simulation agent including a plurality of attributes; generate a probability score for the simulation agent for each of the plurality of touchpoints using a machine learning model based on the plurality of attributes; perform a simulation of the user journey based on the probability score; and generate a text describing the user journey based on the simulation.

An apparatus, system, and method for user journey evaluation are described. One or more aspects of the apparatus, system, and method include at least one processor; at least one memory including instructions executable by the at least one processor; an agent generator component configured to generate a simulation agent including a plurality of attributes; a machine learning model configured to generate a probability score for the simulation agent based on the plurality of attributes; and a simulator component configured to perform a simulation of a user journey based on the probability score.

### BRIEF DESCRIPTION OF THE DRAWINGS

FIG. 1 shows an example of a journey evaluation system according to aspects of the present disclosure.

FIG. 2 shows an example of a journey evaluation apparatus according to aspects of the present disclosure.

FIG. 3 shows an example of a journey evaluation pipeline according to aspects of the present disclosure.

FIG. 4 shows an example of an agent according to aspects of the present disclosure.

FIG. 5 shows an example of a journey evaluation indicating bottlenecks according to aspects of the present disclosure.

FIG. 6 shows an example of a journey evaluation indicating optimizations according to aspects of the present disclosure.

FIG. 7 shows an example of a method for evaluating a user journey path according to aspects of the present disclosure.

FIG. 8 shows an example of a method for generating a user journey evaluation according to aspects of the present disclosure.

FIG. 9 shows an example of a computing device according to aspects of the present disclosure.

### DETAILED DESCRIPTION

User journeys model the various stages a user can take in engaging with a company or service. A user journey can include stages such as initial discovery, evaluation, decision-making, purchasing, and post-purchase experiences. They provide a comprehensive perspective of the user experience, including insights about user behaviors, preferences, and pain points, thus facilitating strategic decision-making.

In conventional systems, content providers design and deploy a user journey and then collect and analyze data from users at each stage. This data might include information about what decisions the user made at each stage. The insights gleaned from this data can be used to develop improved user journeys in the future.

In some cases, however, it can be costly to deploy unoptimized user journeys. For example, if the user journey includes stages with non-optimal parameters or communication types, a user might be disinclined to continue their journey, and may even abandon future interactions with the brand.

Accordingly, embodiments of the present disclosure are configured to evaluate a user journey before deployment. In some cases, embodiments generate a plurality of simulation agents that have attributes based on user data and use a machine learning model to predict each simulation agent's decision at each stage (e.g. touchpoint) in the user journey. Embodiments are configured to extract metrics and different insights about the user journey based on the results of this simulation.

As used herein, “user journey” refers to a model that represents one or more paths a user can take in engaging with a content provider, brand, or service. In some examples, a user journey is represented by a graph structure that includes one or more nodes which represent touchpoints.

As used herein, a “touchpoint” refers to an interaction with the user within the user journey. In some examples, there are touchpoints for sending an email to the user, sending a push notification, launching an application or service, among others. Touchpoints have one or more parameters, such as an amount of time to wait in between sending messages, which type of message to send, etc.

As used herein, a “simulation agent” refers to a data structure that represents a user during a simulation. In some examples, an agent generator component generates one or more simulation agents, and each simulation agent includes a set of attributes. The attributes include values that are sampled from a distribution of historical data that includes values from previous users.

As used herein, a “user journey evaluation” refers to a text that includes information that describes a user journey. In some examples, the text includes a set of values that indicate a predicted outcome of each touchpoint. In some embodiments, the predicted outcome includes a percentage of users that continue the user journey at that touchpoint. Embodiments of the text include a data structure such as a JSON object that includes a list of properties representing the metrics and the insights. In some embodiments, the text is processed to extract and display the results in a graphical user interface (GUI), e.g., overlaid on the user journey graph.

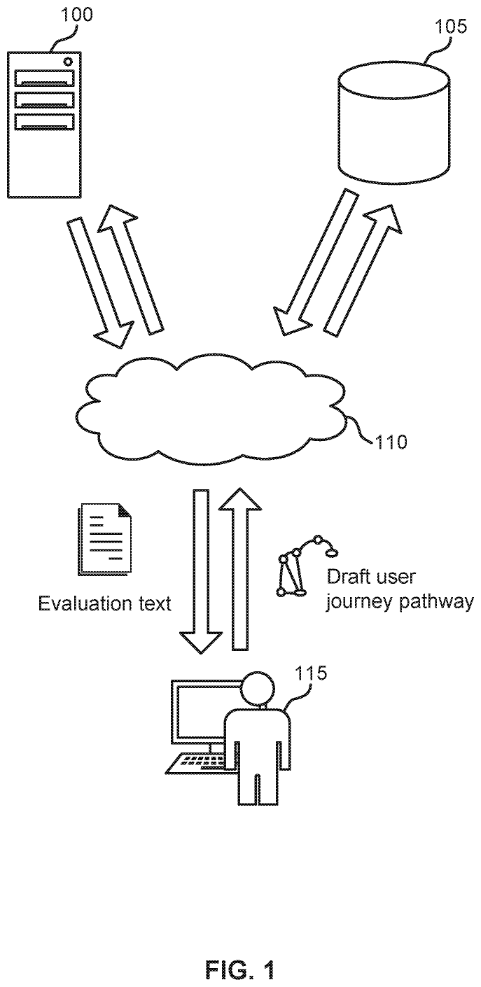

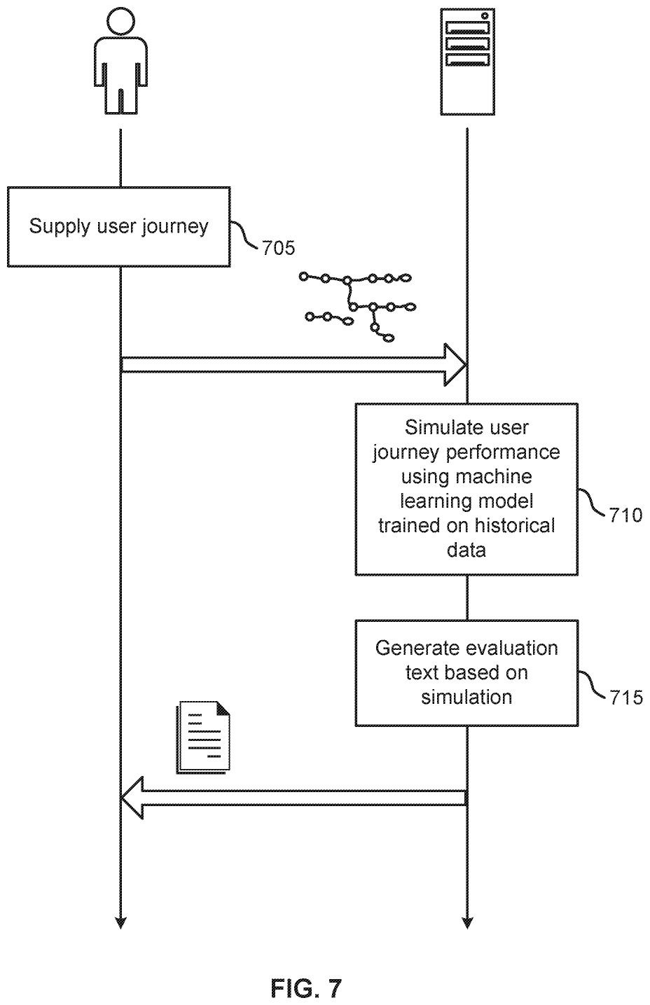

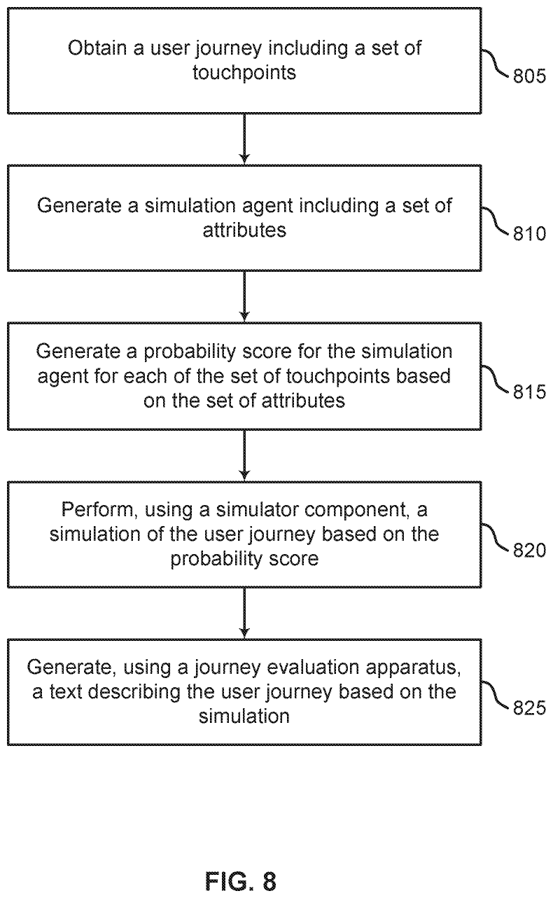

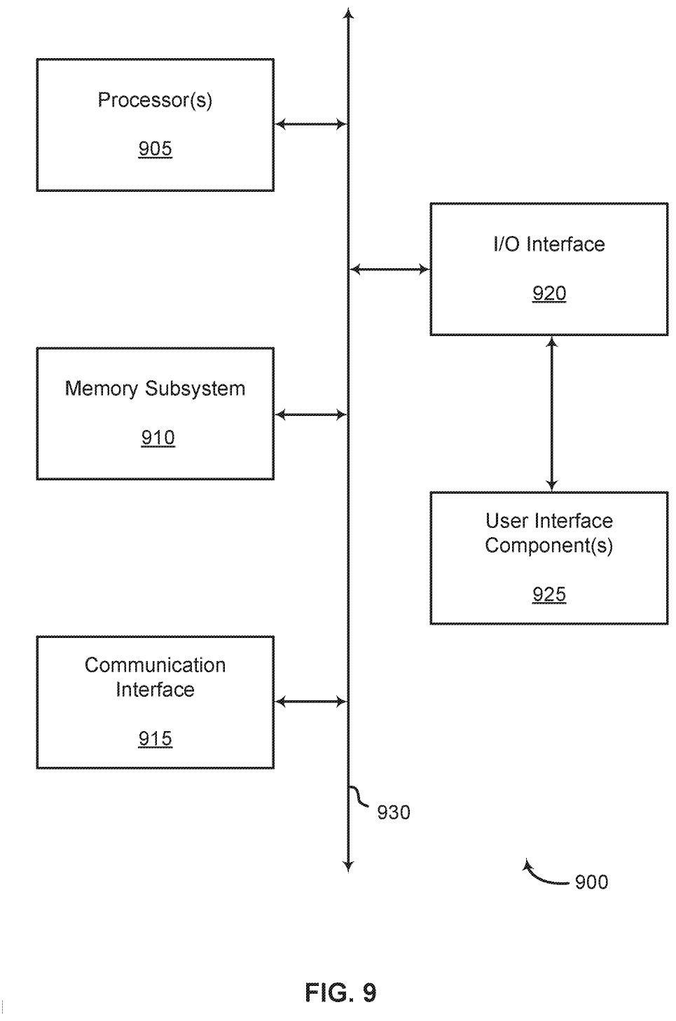

A user journey evaluation apparatus, as well as examples of insights that the user journey evaluation apparatus is configured to extract from the user journey, is described with reference to FIGS. 1-6. Methods for evaluating a user journey are described with reference to FIG. 7-8. A computing device configured to implement a user journey evaluation apparatus is described with reference to FIG. 9.

### Journey Evaluation System

An apparatus for user journey evaluation is described. One or more aspects of the apparatus include at least one processor; at least one memory including instructions executable by the at least one processor; an agent generator component configured to generate a simulation agent including a plurality of attributes; a machine learning model configured to generate a probability score for the simulation agent based on the plurality of attributes; and a simulator component configured to perform a simulation of a user journey based on the probability score. In some aspects, the agent generator component generates a plurality of simulation agents.

Some examples of the apparatus, system, and method further include a bottleneck detection component configured to detect a bottleneck among a plurality of touchpoints included in the user journey. Some examples of the apparatus, system, and method further include a journey optimizer component configured to repeat the simulation for each of a plurality of parameter values for each of a plurality of touchpoints included in the user journey, and to select a recommended parameter value from the plurality of parameter values based on the repeated simulation.

FIG. 1 shows an example of a journey evaluation system according to aspects of the present disclosure. The example shown includes journey evaluation apparatus 100, database 105, network 110, and content provider 115.

In one example, content provider 115 designs a draft user journey. The content might create the user journey through a software tool. Content provider 115 then sends the draft user journey to journey evaluation apparatus 100 over network 110. Journey evaluation apparatus 100 simulates the draft user journey by generating one or more simulation agents and predicting outcomes of the simulation agents using a machine learning model. In some examples, the simulation agents are generated based on historical user data stored in database 105. Journey evaluation apparatus 100 then provides a text to content provider 115 that includes predicted metrics of the draft user journey based on the simulation.

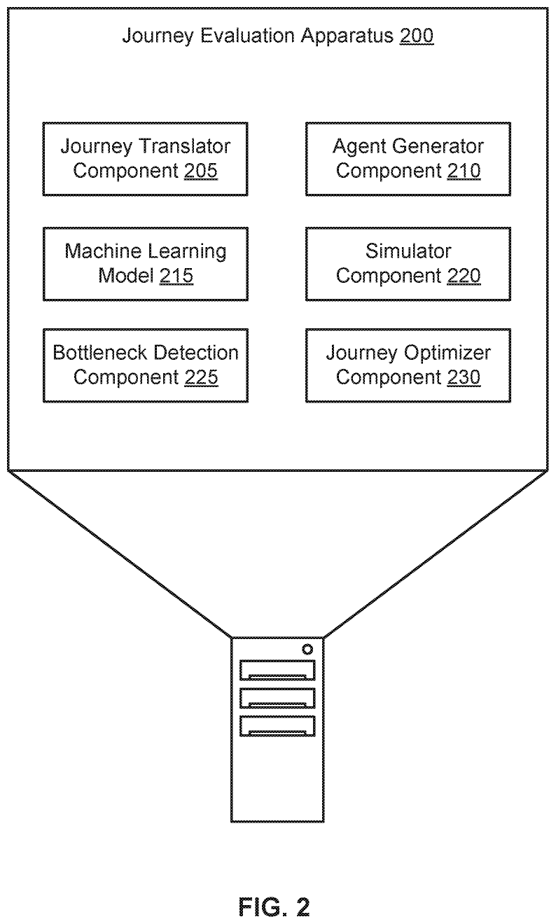

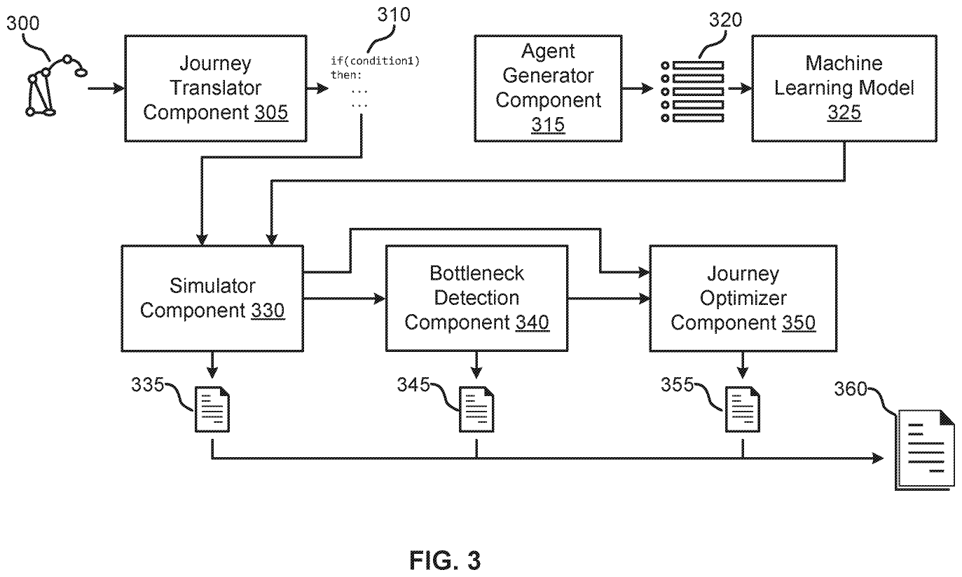

According to some aspects, journey evaluation apparatus 100 obtains, through a user interface, a user journey including a set of touchpoints. In some examples, journey evaluation apparatus 100 generates a text describing the user journey based on a simulation, which will be described in further detail with reference to FIG. 3. In some examples, journey evaluation apparatus 100 prepares a set of machine learning models corresponding to a set of touchpoints in an input user journey, where the probability score for each of the set of touchpoints is generated by a corresponding machine learning model of the set of machine learning models. Journey evaluation apparatus 100 is an example of, or includes aspects of, the corresponding element described with reference to FIG. 2.

Some examples of journey evaluation apparatus 100 are implemented on a server. A server provides one or more functions to users linked by way of one or more of the various networks. In some cases, the server includes a single microprocessor board, which includes a microprocessor responsible for controlling all aspects of the server. In some cases, a server uses microprocessor and protocols to exchange data with other devices/users on one or more of the networks via hypertext transfer protocol (HTTP), and simple mail transfer protocol (SMTP), although other protocols such as file transfer protocol (FTP), and simple network management protocol (SNMP) can also be used. In some cases, a server is configured to send and receive hypertext markup language (HTML) formatted files (e.g., for displaying web pages). In various embodiments, a server comprises a general purpose computing device, a personal computer, a laptop computer, a mainframe computer, a super computer, or any other suitable processing apparatus.

Database 105 is configured to store various data and information used by the journey evaluation system. In some examples, database 105 stores parameters used by one or more machine learning models of journey evaluation apparatus 100, as well as historical user data. A database is an organized collection of data. For example, a database stores data in a specified format known as a schema. A database can be structured as a single database, a distributed database, multiple distributed databases, or an emergency backup database. In some cases, a database controller manages data storage and processing in a database. In some cases, the user interacts with a database controller. In other cases, a database controller operates automatically without user interaction.

Network 110 facilitates the transfer of information between journey evaluation apparatus 100, database 105, and content provider 115. Network 110 can be referred to as a “cloud.” A cloud is a computer network configured to provide on-demand availability of computer system resources, such as data storage and computing power. In some examples, the cloud provides resources without active management by the user. The term cloud is sometimes used to describe data centers available to many users over the Internet. Some large cloud networks have functions distributed over multiple locations from central servers. A server is designated an edge server if it has a direct or close connection to a user. In some cases, a cloud is limited to a single organization. In other examples, the cloud is available to many organizations. In one example, a cloud includes a multi-layer communications network comprising multiple edge routers and core routers. In another example, a cloud is based on a local collection of switches in a single physical location.

FIG. 2 shows an example of a journey evaluation apparatus 200 according to aspects of the present disclosure. The example shown includes journey evaluation apparatus 200, journey translator component 205, agent generator component 210, machine learning model 215, simulator component 220, bottleneck detection component 225, and journey optimizer component 230.

Embodiments of journey evaluation apparatus 200 include several components. The term ‘component’ is used to partition the functionality enabled by the processor(s) and the executable instructions included in the computing device used to implement journey evaluation apparatus 200 (such as the computing device described with reference to FIG. 9). The partitions can be implemented physically, such as through the use of separate circuits or processors for each component, or can be implemented logically via the architecture of the code executable by the processors.

Journey translator component 205 is configured to translate a graphical representation of a user journey into a workflow logic, such as code including a series of “if-else” statements. In some cases, this translation step produces code that is executable by simulator component 220 to run a simulation with one or more simulation agents. In some embodiments, journey translator component 205 is omitted.

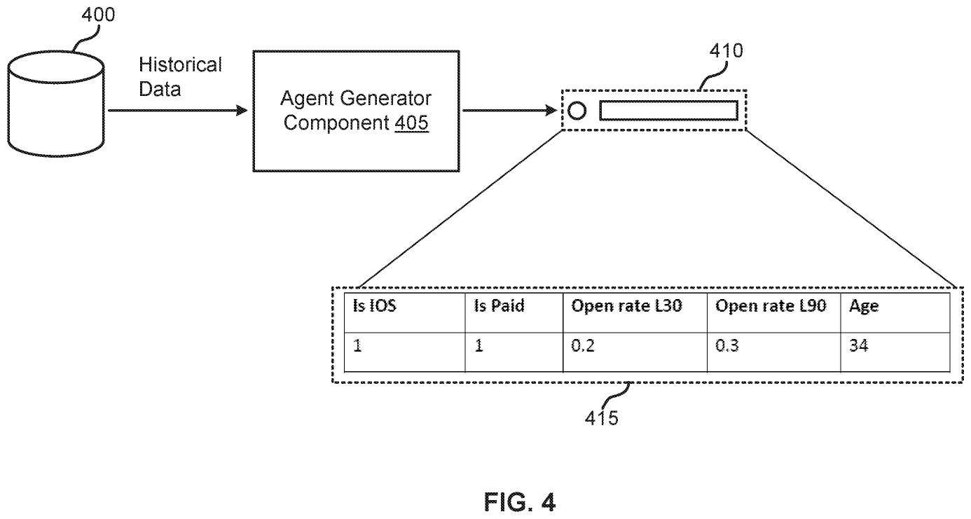

Agent generator component 210 is configured to generate simulation agents. In some examples, a simulation agent is a set of attributes and corresponding attribute values. Embodiments of agent generator component 210 sample from a historical user behavior data distribution. In some cases, agent generator component 210 samples using a Markov-chain Monte Carlo (MCMC) method to generate the simulation agents. Agent generator component 210 is an example of, or includes aspects of, the corresponding element described with reference to FIGS. 3 and 4.

Machine learning model 215 is configured to process a set of inputs and predict an outcome. In some embodiments, the set of inputs includes the attributes and attribute values from an agent. In at least one embodiment, machine learning model 215 comprises a plurality of a machine learning models. In some embodiments, each of the plurality of machine learning models corresponds to a touchpoint or a type of touchpoint, and is configured to predict an outcome for its associated touchpoint. An outcome includes a probability for an agent to pass to a certain path after a touchpoint. For example, the probability might be an “open” probability or a “click” probability, and correspond to the probability that a particular simulation agent will continue along the user journey rather than proceeding to an “END” node.

Embodiments of machine learning model 215 include an artificial neural network (ANN). An ANN is a hardware or a software component that includes a number of connected nodes (i.e., artificial neurons), which loosely correspond to the neurons in a human brain. Each connection, or edge, transmits a signal from one node to another (like the physical synapses in a brain). When a node receives a signal, it processes the signal and then transmits the processed signal to other connected nodes. In some cases, the signals between nodes comprise real numbers, and the output of each node is computed by a function of the sum of its inputs. In some examples, nodes determine their output using other mathematical algorithms (e.g., selecting the max from the inputs as the output) or any other suitable algorithm for activating the node. Each node and edge is associated with one or more node weights that determine how the signal is processed and transmitted.

During the training process, these weights are adjusted to improve the accuracy of the result (i.e., by minimizing a loss function which corresponds in some way to the difference between the current result and the target result). The weight of an edge increases or decreases the strength of the signal transmitted between nodes. In some cases, nodes have a threshold below which a signal is not transmitted at all. In some examples, the nodes are aggregated into layers. Different layers perform different transformations on their inputs. The initial layer is known as the input layer and the last layer is known as the output layer. In some cases, signals traverse certain layers multiple times. Machine learning model 215 is an example of, or includes aspects of, the corresponding element described with reference to FIG. 3.

Simulator component 220 is configured to perform a simulation that runs the simulation agents through a user journey. According to some aspects, simulator component 220 executes the workflow logic from journey translator component 205, with the logic flow for each simulation agent (e.g., the path of the simulation agent through the if-else blocks) determined by predicted outcomes from machine learning model 215. For example, machine learning model 215 predicts an outcome for an agent at a touchpoint, and selectively execute blocks of code based on the outcome. According to some aspects, simulator component 220 records the outcomes for the simulation agents to generate metrics for the user journey. Metrics can include, but are not limited to, the percentage of simulation agents that pass through each path after the touchpoint. Simulator component 220 is an example of, or includes aspects of, the corresponding element described with reference to FIG. 3.

Bottleneck detection component 225 is configured to identify touchpoints that are bottlenecks. Bottleneck detection component 225 uses data from simulator component 220 and identify a touchpoint that has an overall low probability for simulation agents to pass. In one example, bottleneck detection component 225 determines that a touchpoint is a bottleneck if the percentage of simulation agents that pass through it is lower than a threshold percent. This threshold can be preconfigured, or determined based on the touchpoint, or based on the current user journey. Bottleneck detection component 225 is an example of, or includes aspects of, the corresponding element described with reference to FIG. 3.

Journey optimizer component 230 is configured to identify touchpoints that are sensitive to changes, or touchpoints that can be optimized by changing their parameters or their type. According to some aspects, journey optimizer component 230 is configured to repeat the simulation for each of a plurality of parameter values for each of a plurality of touchpoints included in the user journey, and to select a recommended parameter value from the plurality of parameter values based on the repeated simulation. Journey optimizer component 230 is an example of, or includes aspects of, the corresponding element described with reference to FIG. 3.

According to some aspects, journey optimizer component 230 modifies a parameter value associated with a touchpoint of the set of touchpoints. In some examples, journey optimizer component 230 performs a sensitivity analysis based on the simulation and the repeated simulation, where the text is based on the sensitivity analysis. In some examples, journey optimizer component 230 identifies a set of parameter values for a touchpoint of the set of touchpoints. In some examples, journey optimizer component 230 selects a recommended parameter value from the set of parameter values based on the repeated simulation, where the text is based on the recommended parameter value. In some examples, journey optimizer component 230 performs an optimization of the user journey, where the text includes a recommended modification based on the optimization.

FIG. 3 shows an example of a journey evaluation pipeline according to aspects of the present disclosure. The example shown includes user journey graph 300, journey translator component 305, user journey logic 310, agent generator component 315, simulation agents 320, machine learning model 325, simulator component 330, simulator output 335, bottleneck detection component 340, bottleneck detection output 345, journey optimizer component 350, journey optimizer output 355, and journey evaluation 360. The components described with reference to FIG. 3 are examples of, or include aspects of, the corresponding components described with reference to FIG. 2.

In the example shown, a journey evaluation apparatus such as the one described with reference to FIG. 2 receives a user journey graph 300. Journey translator component 305 transforms user journey graph 300 into user journey logic 310. Examples of journey logic 310 include a series of if-else statements which can be used by simulator component 330 to simulate a user journey.

In this example, agent generator component 315 creates agents 320 that each include a plurality of attributes and attribute values. An example of an agent will be described with reference to FIG. 4.

Machine learning model 325 processes the attributes of an agent as input and predicts an outcome for the simulation agent. In some examples, machine learning model 325 comprises a model for each type of touchpoint included in the original user journey. Embodiments of machine learning model 325 include a model for predicting an agent's outcome to a push notification, another model for predicting the simulation agent's outcome to an email message, another model for a text message, etc.

Simulator component 330 runs agents 320 through user journey logic 310 to simulate the user journey. In some examples, an agent's path after a touchpoint corresponds to whether or not the simulation agent responded to the interaction in the touchpoint; for example, whether or not the simulation agent clicked or opened a message. Embodiments of machine learning model 325 predict a probability for each simulation agent at each touchpoint that represents the simulation agent's probability to respond to the message, e.g., continue in that path. Then, simulator component 330 uses a random number generator to simulate that probability. In an example, if the machine learning model 325 predicts that an agent with a particular set of attributes has a 37% chance to proceed, then simulator component 330 generates a number between 0 and 1, and if the generated number is 0.37 or lower, simulate the simulation agent's passing through the checkpoint. In some embodiments, no random number generator is used, and simulator component 330 aggregates the probability outcomes from machine learning model 325 without further processing to generate metrics as simulator output 335.

Bottleneck detection component 340 is configured to process the aggregated outcomes for each touchpoint from simulator component 330 to identify bottleneck touchpoints. A bottleneck touchpoint is a touchpoint that has a relatively low probability for simulation agents to continue through. Some embodiments of bottleneck detection component 340 direct simulator component 330 to run a first simulation up to a particular node (e.g., a touchpoint), and then to run a second simulation for all nodes thereafter, and to compare the performance of the first simulation to the performance of the second simulation. If there is a significant performance drop between the two simulations, then this can indicate that the node corresponds to a bottleneck touchpoint. Bottleneck detection component 340 generates a summary of the detected bottlenecks as bottleneck detection output 345.

Journey optimizer component 350 is configured to identify sensitive touchpoints, best parameter ranges for touchpoints, and suggested changes to the types of touchpoints. Embodiments of journey optimizer component 350 are configured to run multiple simulations to test variations on touchpoints within a user journey.

In some aspects, journey optimizer component 350 performs a touchpoint sensitivity analysis by iterating through all touchpoints in the user journey. For each touchpoint, journey optimizer component 350 directs simulator component 330 to run a simulation for a base set of parameter values P, and then to run additional simulations with some variance ε to each parameter of the base parameters. Then, journey optimizer component 350 compares the results of the multiple simulations to identify any sensitive parameters. In some examples, the sensitivity analysis includes changing the number or the attributes of the simulation agents for a touchpoint to identify sensitivity to user composition.

In some aspects, journey optimizer component 350 identifies the best ranges for the values of each parameter in a touchpoint. In some examples, journey optimizer component 350 samples a set of values over a range within each parameter of a touchpoint. In some examples, the sampling method is an equal interval sampling, based on a distribution, based on a logarithm of the values, or some other method. Then, journey optimizer component 350 directs simulator component 330 to run a simulation for each value in the set. Journey optimizer component 350 then compares a performance of each of the simulations to determine the best value range for the parameter of the touchpoint. In some examples, the performance measurement is based on predicted user outcomes from machine learning model 325.

In some aspects, journey optimizer component 350 identifies possible changes to a touchpoint type or message modality. In some examples, journey optimizer component 350 randomly generates a new set of touchpoints including new parameters, and runs a simulation to evaluate the performance of the generated parameter set. Then, journey optimizer component 350 generates a new set of parameters based on the current set of parameters. Journey optimizer component 350 generates new parameters using various methods, such as particle swarm algorithm or tabu search. In some embodiments, journey optimizer component 350 repeats this process until a desired performance level is reached. Once an optimal set of touchpoints and associated parameters have been found, journey optimizer component 350 summarizes the differences from the initial user journey in journey optimizer output 355, along with the results from the sensitivity analysis and the best parameter range analysis.

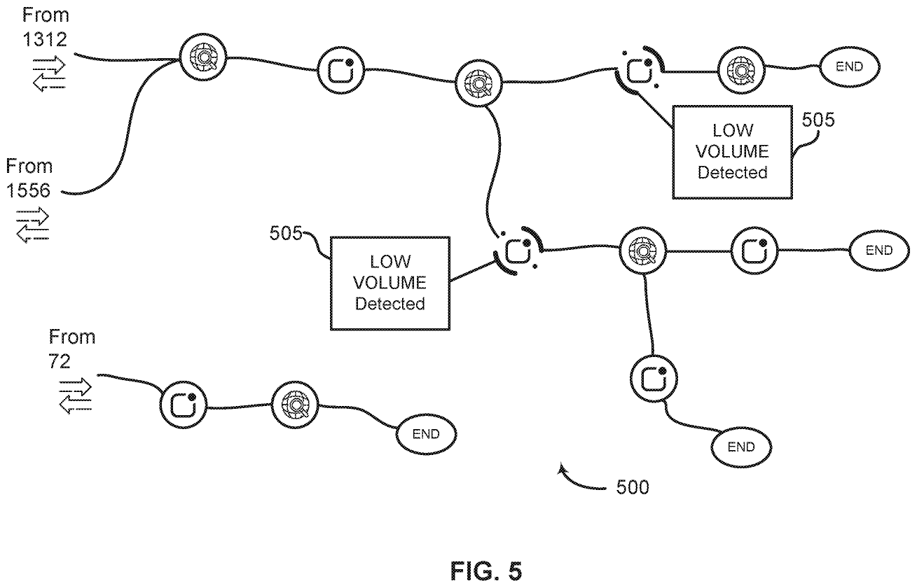

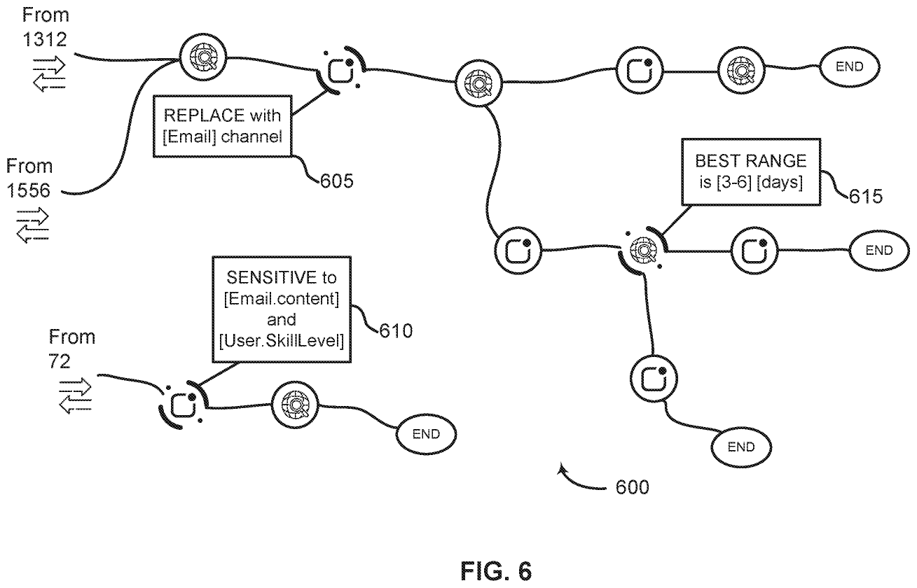

According to some aspects, simulator output 335, bottleneck detection output 345, journey optimizer output 355, or a combination thereof is output as journey evaluation 360. In some examples, this is a text or data structure including a set of results. In at least one example, journey evaluation 360 is processed and displayed as an overlay to user journey graph 300. Examples of a journey evaluation 360 will be described with reference to FIGS. 5 and 6.

FIG. 4 shows an example of an agent according to aspects of the present disclosure. The example shown includes database 400, agent generator component 405, simulation agent 410, and attributes 415. Agent generator component 405 is an example of, or includes aspects of, the corresponding element described with reference to FIGS. 2 and 3. Database 400 is an example of, or includes aspects of, the corresponding element described with reference to FIG. 1.

In this example, agent generator component 405 samples attributes and attribute values from a historical user behavior data distribution. In some embodiments, agent generator component 405 samples using a Markov-chain Monte Carlo (MCMC) method, though. The simulation agent 410 includes the sampled attributes as attributes 415. In the example shown, attributes 415 include properties of an agent's device, its subscription status, its historical open rate for the last 30 days, its historical open rate for the last 90 days, and its simulated age. Embodiments are not limited thereto, however, and simulation agents can be generated with thousands of attributes. In some cases, some simulation agents are generated with a different set of attributes from other simulation agents. In some cases, all agents are generated with the same set of attributes, with varying attribute values.

FIG. 5 shows an example of a journey evaluation 500 indicating bottlenecks according to aspects of the present disclosure. The example shown includes journey evaluation 500 and detected bottleneck(s) 505. Journey evaluation 500 is an example of, or includes aspects of, the corresponding element described with reference to FIGS. 3 and 6.

In this example, a journey evaluation 500 is overlaid on an input user journey graph. In some cases, the input user journey graph is processed via the methods described with reference to FIG. 3. For example, the bottleneck detection component has iterated through each node in the graph, and has identified two nodes corresponding to push-notification-type touchpoints that are potential bottlenecks.

In some cases, the user journey graph includes a plurality of touchpoints. In one example, icons that include a rounded rectangle and a dot correspond to a ‘push notification’ type touchpoint, and icons that include a globe correspond to an app or service launch type touchpoint, though embodiments are not limited thereto. Additionally, some graphs include “jumps” (e.g., the leftmost nodes including arrows) that represent a continuation of a path from a previous touchpoint.

In some examples, a detected bottleneck(s) 505 is determined by aggregating predictions for a plurality of simulation agents at the touchpoint. In some cases, a detected bottleneck(s) 505 can be determined by running a first simulation of the user journey through the nodes preceding the node currently being evaluated, and a second simulation of the user journey through the nodes proceeding the node currently being evaluated. If there is a large drop in performance (for example, as measured by the number of simulation agents reaching a desired END-block), then the node can be identified as detected bottleneck(s) 505.

In some cases, the system overlays the detected bottleneck(s) 505 onto the input user journey graph as part of a user journey evaluation. In an example, a content provider instructs the system to evaluate the user journey, and then clicks a button that says “Show potential bottlenecks” or similar. In this way, the content provider is made aware of a possible bottleneck in their design, and they can choose to adjust their design in response.

Embodiments are configured to generate different types of user journey evaluations. FIG. 5 describes a case in which the user journey evaluation included identifications of potential bottlenecks. Another possible user journey evaluation includes generating a predetermined number of simulation agents, such as 100,000, and running a simulation of the user journey to determine the number of simulation agents that reach each node, as well as their composition (e.g., the ranges of values in the simulation agents' attributes). Some user journey evaluations further include identifying nodes that are sensitive to parameters, identifying the best parameter ranges for the nodes, and suggesting possible changes to the nodes.

FIG. 6 shows an example of a journey evaluation 600 indicating optimizations according to aspects of the present disclosure. The example shown includes journey evaluation 600, touchpoint replacement optimization 605, touchpoint sensitivity indicator 610, and touchpoint best range suggestion 615. The touchpoint replacement optimization 605, touchpoint sensitivity indicator 610, and touchpoint best range suggestion 615 are generated by a journey optimization component using the methods described with reference to FIGS. 2-3.

In this example, touchpoint replacement optimization 605 is a suggestion to replace the indicated node with a touchpoint of a different type. For instance, the node might have originally been a “push-notification” type, and, after running a series of simulations as described with reference to FIG. 3, the system determines that an “email” type touchpoint will have higher conversion, retention etc. In some examples, touchpoint replacement optimization 605 suggests both a change in the type of touchpoint, as well as the best range of parameters for the new type.

Touchpoint sensitivity indicator 610 alerts a content provider (e.g., the creator of the initial user journey) that the indicated touchpoint is sensitive to changes in its parameters, or in the composition of users that reach the indicated touchpoint. In this example, touchpoint sensitivity indicator 610 alerts the content provider that changing the content of the email message sent at this point in the user journey can significantly change the performance of the user journey. This allows the content provider to make informed decisions in future design iterations of the user journey.

Touchpoint best range suggestion 615 is a suggestion by the system to change the current parameters of the indicated touchpoint to the suggested range. In this particular example, the touchpoint is a “wait-type” touchpoint that pauses the user journey for an amount of time before, for example, sending a communication to the user.

### User Journey Evaluation

A method for user journey evaluation is described. One or more aspects of the method include obtaining, through a user interface, a user journey including a plurality of touchpoints; generating, using an agent generator component, a simulation agent including a plurality of attributes; generating, using a machine learning model, a probability score for the simulation agent for each of the plurality of touchpoints based on the plurality of attributes; performing, using a simulator component, a simulation of the user journey based on the probability score; and generating, using a journey evaluation apparatus, a text describing the user journey based on the simulation.

Some examples of the method, apparatus, non-transitory computer readable medium, and system further include generating workflow logic based on the user journey, wherein the simulation is based on the workflow logic. Some examples further include generating a plurality of simulation agents, wherein the simulation is based on the plurality of simulation agents.

Some examples of the method, apparatus, non-transitory computer readable medium, and system further include preparing a plurality of machine learning models corresponding to the plurality of touchpoints, wherein the probability score for each of the plurality of touchpoints is generated by a corresponding machine learning model of the plurality of machine learning models. Some examples of the method, apparatus, non-transitory computer readable medium, and system further include generating an evaluation of each of the plurality of touchpoints, wherein the text includes the evaluation. Some examples further include detecting a bottleneck among the plurality of touchpoints, wherein the text is generated based on the detected bottleneck. Some examples further include performing an optimization of the user journey, wherein the text includes a recommended modification based on the optimization.

Some examples of the method, apparatus, non-transitory computer readable medium, and system further include modifying a parameter value associated with a touchpoint of the plurality of touchpoints. Some examples further include repeating the simulation based on the modified parameter value. Some examples further include performing a sensitivity analysis based on the simulation and the repeated simulation, wherein the text is based on the sensitivity analysis.

Some examples of the method, apparatus, non-transitory computer readable medium, and system further include identifying a plurality of parameter values for a touchpoint of the plurality of touchpoints. Some examples further include repeating the simulation for each of the plurality of parameter values. Some examples further include selecting a recommended parameter value from the plurality of parameter values based on the repeated simulation, wherein the text is based on the recommended parameter value.

FIG. 7 shows an example of a method for evaluating a user journey path according to aspects of the present disclosure. In some examples, these operations are performed by a system including a processor executing a set of codes to control functional elements of an apparatus. Additionally or alternatively, certain processes are performed using special-purpose hardware. Generally, these operations are performed according to the methods and processes described in accordance with aspects of the present disclosure. In some cases, the operations described herein are composed of various substeps, or are performed in conjunction with other operations.

At operation 705, a content provider supplies a user journey. In some examples, the content provider designs a first iteration of a user journey using a software tool. Then, the content provider supplies the user journey to the system via a user interface such as a graphical user interface (GUI).

At operation 710, the system simulates user journey performance using a machine learning model trained on historical data. In some examples, the system simulates the user journey using the methods described with reference to FIG. 3. The system generates a plurality of simulation agents, which are also based on the historical data, and then simulates the paths of the simulation agents through the user journey, where the user journey includes a plurality of nodes corresponding to touchpoints. At each touchpoint, the system uses a machine learning model to predict the simulation agent's decision. In some cases, the system uses a plurality of machine learning models, each corresponding to a touchpoint or type of touchpoint. According to some aspects, the machine learning models are trained using historical data in a process that involves iteratively updating parameters of the model based on a gradient determined from a loss function. Examples of the loss function are based on a difference between a predicted outcome of a user with the actual outcome of the user, where the model's prediction is based on the user's set of attributes and the touchpoint type.

At operation 715, the system generates an evaluation text based on the simulation. In some examples, the system includes outputs from a simulation component, a bottleneck detection component, and a journey optimizer component as described with reference to FIG. 3. The evaluation text includes metrics and insights from the simulation, such as the predicted number and composition of users who pass through or reach each touchpoint, predicted bottleneck touchpoints, touchpoints that are sensitive to changes in their parameters, suggested best ranges for the touchpoint parameters, and suggested improvements to each touchpoint. In some embodiments, information from the evaluation text is transformed to visual indicators which are overlaid onto the user journey graph.

FIG. 8 shows an example of a method for generating a user journey evaluation according to aspects of the present disclosure. In some examples, these operations are performed by a system including a processor executing a set of codes to control functional elements of an apparatus. Additionally or alternatively, certain processes are performed using special-purpose hardware. Generally, these operations are performed according to the methods and processes described in accordance with aspects of the present disclosure. In some cases, the operations described herein are composed of various substeps, or are performed in conjunction with other operations.

At operation 805, the system obtains, through a user interface, a user journey including a set of touchpoints. As described with reference to FIGS. 1-3, in some cases, a content provider designs a user journey, and provides it to the system for evaluation through the user interface.

At operation 810, the system generates, using an agent generator component, a simulation agent including a set of attributes. In some cases, the operations of this step refer to, or may be performed by, an agent generator component as described with reference to FIGS. 2-4. Embodiments of the agent generator component generate one simulation agent for the simulation or multiple simulation agents. Examples of the set of attributes include attributes based on a historical user data distribution. For example, for each simulation agent, the agent generator component samples the historical user data distribution to obtain values for the attributes, e.g., using an MCMC method.

At operation 815, the system generates, using a machine learning model, a probability score for the simulation agent for each of the set of touchpoints based on the set of attributes. In some cases, the operations of this step refer to, or may be performed by, a machine learning model as described with reference to FIGS. 2 and 3. In at least some embodiments, the machine learning model comprises multiple models that are configured to predict the outcomes for each of the set of touchpoints, respectively, using the set of attributes of the simulation agent as input.

At operation 820, the system performs, using a simulator component, a simulation of the user journey based on the probability score. In some cases, the simulation includes modeling the path of the simulation agent through the set of touchpoints, where the path is based on the probability scores of the touchpoints. In an example, the simulator component simulates whether or not the simulation agent passes through a “click” or “open” touchpoint based on the probability predicted by the machine learning model for that touchpoint.

At operation 825, the system generates, using a journey evaluation apparatus, a text describing the user journey based on the simulation. In an example, the system aggregates data about the simulation agent, its attributes, and its choices throughout the simulation. From this aggregated data, the system generates metrics and insights about the user journey, such as those described with reference to FIGS. 3-6.

FIG. 9 shows an example of a computing device 900 according to aspects of the present disclosure. The example shown includes computing device 900, processor(s) 905, memory subsystem 910, communication interface 915, I/O interface 920, user interface component(s), and channel 930.

In some embodiments, computing device 900 is an example of, or includes aspects of, journey evaluation apparatus 100 of FIG. 1. In some embodiments, computing device 900 includes one or more processors 905 that can execute instructions stored in memory subsystem 910 to obtain a user journey including a plurality of touchpoints; generate a simulation agent including a plurality of attributes; generate, using a machine learning model, a probability score for the simulation agent for each of the plurality of touchpoints based on the plurality of attributes; perform a simulation of the user journey based on the probability score; and generate a text describing the user journey based on the simulation.

According to some aspects, computing device 900 includes one or more processors 1005. In some cases, a processor is an intelligent hardware device, (e.g., a general-purpose processing component, a digital signal processor (DSP), a central processing unit (CPU), a graphics processing unit (GPU), a microcontroller, an application specific integrated circuit (ASIC), a field programmable gate array (FPGA), a programmable logic device, a discrete gate or transistor logic component, a discrete hardware component, or a combination thereof. In some cases, a processor is configured to operate a memory array using a memory controller. In other cases, a memory controller is integrated into a processor. In some cases, a processor is configured to execute computer-readable instructions stored in a memory to perform various functions. In some embodiments, a processor includes special purpose components for modem processing, baseband processing, digital signal processing, or transmission processing.

According to some aspects, memory subsystem 910 includes one or more memory devices. Examples of a memory device include random access memory (RAM), read-only memory (ROM), or a hard disk. Examples of memory devices include solid state memory and a hard disk drive. In some examples, memory is used to store computer-readable, computer-executable software including instructions that, when executed, cause a processor to perform various functions described herein. In some cases, the memory contains, among other things, a basic input/output system (BIOS) which controls basic hardware or software operation such as the interaction with peripheral components or devices. In some cases, a memory controller operates memory cells. For example, the memory controller can include a row decoder, column decoder, or both. In some cases, memory cells within a memory store information in the form of a logical state.

According to some aspects, communication interface 915 operates at a boundary between communicating entities (such as computing device 900, one or more user devices, a cloud, and one or more databases) and channel 930 and can record and process communications. In some cases, communication interface 915 is provided to enable a processing system coupled to a transceiver (e.g., a transmitter and/or a receiver). In some examples, the transceiver is configured to transmit (or send) and receive signals for a communications device via an antenna.

According to some aspects, I/O interface 920 is controlled by an I/O controller to manage input and output signals for computing device 900. In some cases, I/O interface 920 manages peripherals not integrated into computing device 900. In some cases, I/O interface 920 represents a physical connection or port to an external peripheral. In some cases, the I/O controller uses an operating system such as iOS®, ANDROID®, MS-DOS®, MS-WINDOWS®, OS/2®, UNIX®, LINUX®, or other known operating system. In some cases, the I/O controller represents or interacts with a modem, a keyboard, a mouse, a touchscreen, or a similar device. In some cases, the I/O controller is implemented as a component of a processor. In some cases, a content provider interacts with a device via I/O interface 920 or via hardware components controlled by the I/O controller.

According to some aspects, user interface component(s) 925 enable a content provider to interact with computing device 900. In some cases, user interface component(s) 925 include an audio device, such as an external speaker system, an external display device such as a display screen, an input device (e.g., a remote control device interfaced with a user interface directly or through the I/O controller), or a combination thereof. In some cases, user interface component(s) 925 include a GUI.

The description and drawings described herein represent example configurations and do not represent all the implementations within the scope of the claims. For example, the operations and steps may be rearranged, combined or otherwise modified. Also, structures and devices may be represented in the form of block diagrams to represent the relationship between components and avoid obscuring the described concepts. Similar components or features may have the same name but may have different reference numbers corresponding to different figures.

Some modifications to the disclosure may be readily apparent to those skilled in the art, and the principles defined herein may be applied to other variations without departing from the scope of the disclosure. Thus, the disclosure is not limited to the examples and designs described herein, but is to be accorded the broadest scope consistent with the principles and novel features disclosed herein.

The described methods may be implemented or performed by devices that include a general-purpose processor, a digital signal processor (DSP), an application specific integrated circuit (ASIC), a field programmable gate array (FPGA) or other programmable logic device, discrete gate or transistor logic, discrete hardware components, or any combination thereof. A general-purpose processor may be a microprocessor, a conventional processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration). Thus, the functions described herein may be implemented in hardware or software and may be executed by a processor, firmware, or any combination thereof. If implemented in software executed by a processor, the functions may be stored in the form of instructions or code on a computer-readable medium.

Computer-readable media includes both non-transitory computer storage media and communication media including any medium that facilitates transfer of code or data. A non-transitory storage medium may be any available medium that can be accessed by a computer. For example, non-transitory computer-readable media can comprise random access memory (RAM), read-only memory (ROM), electrically erasable programmable read-only memory (EEPROM), compact disk (CD) or other optical disk storage, magnetic disk storage, or any other non-transitory medium for carrying or storing data or code.

Also, connecting components may be properly termed computer-readable media. For example, if code or data is transmitted from a website, server, or other remote source using a coaxial cable, fiber optic cable, twisted pair, digital subscriber line (DSL), or wireless technology such as infrared, radio, or microwave signals, then the coaxial cable, fiber optic cable, twisted pair, DSL, or wireless technology are included in the definition of medium. Combinations of media are also included within the scope of computer-readable media.

In this disclosure and the following claims, the word “or” indicates an inclusive list such that, for example, the list of X, Y, or Z means X or Y or Z or XY or XZ or YZ or XYZ. Also the phrase “based on” is not used to represent a closed set of conditions. For example, a step that is described as “based on condition A” may be based on both condition A and condition B. In other words, the phrase “based on” shall be construed to mean “based at least in part on.” Also, the words “a” or “an” indicate “at least one.”

What is claimed is:

1. A method comprising:
obtaining, through a user interface, a user journey including a plurality of touchpoints;
generating, using an agent generator component, a simulation agent including a plurality of attributes;
generating, using a machine learning model, a probability score for the simulation agent for each of the plurality of touchpoints based on the plurality of attributes;
performing, using a simulator component, a simulation of the user journey based on the probability score; and
generating, using a journey evaluation apparatus, a text describing the user journey based on the simulation.

2. The method of claim 1, further comprising:
generating workflow logic based on the user journey, wherein the simulation is based on the workflow logic.

3. The method of claim 1, further comprising:
generating a plurality of simulation agents, wherein the simulation is based on the plurality of simulation agents.

4. The method of claim 1, further comprising:
preparing a plurality of machine learning models corresponding to the plurality of touchpoints, wherein the probability score for each of the plurality of touchpoints is generated by a corresponding machine learning model of the plurality of machine learning models.

5. The method of claim 1, further comprising:
generating an evaluation of each of the plurality of touchpoints, wherein the text includes the evaluation.

6. The method of claim 1, further comprising:
detecting a bottleneck among the plurality of touchpoints, wherein the text is generated based on the detected bottleneck.

7. The method of claim 1, further comprising:
modifying a parameter value associated with a touchpoint of the plurality of touchpoints;
repeating the simulation based on the modified parameter value; and
performing a sensitivity analysis based on the simulation and the repeated simulation, wherein the text is based on the sensitivity analysis.

8. The method of claim 1, further comprising:
identifying a plurality of parameter values for a touchpoint of the plurality of touchpoints;
repeating the simulation for each of the plurality of parameter values; and
selecting a recommended parameter value from the plurality of parameter values based on the repeated simulation, wherein the text is based on the recommended parameter value.

9. The method of claim 1, further comprising:
performing an optimization of the user journey, wherein the text includes a recommended modification based on the optimization.

10. A non-transitory computer readable medium storing code, the code comprising instructions executable by a processor to:
obtain a user journey including a plurality of touchpoints;
generate a simulation agent including a plurality of attributes;
generate a probability score for the simulation agent for each of the plurality of touchpoints using a machine learning model based on the plurality of attributes;
perform a simulation of the user journey based on the probability score; and
generate a text describing the user journey based on the simulation.

11. The non-transitory computer readable medium of claim 10, wherein the code further comprises instructions executable by the processor to:
generate a plurality of simulation agents, wherein the simulation is based on the plurality of simulation agents.

12. The non-transitory computer readable medium of claim 10, wherein the code further comprises instructions executable by the processor to:
prepare a plurality of machine learning models corresponding to the plurality of touchpoints, wherein the probability score for each of the plurality of touchpoints is generated by a corresponding machine learning model of the plurality of machine learning models.

13. The non-transitory computer readable medium of claim 10, wherein the code further comprises instructions executable by the processor to:
generate an evaluation of each of the plurality of touchpoints, wherein the text includes the evaluation.

14. The non-transitory computer readable medium of claim 10, wherein the code further comprises instructions executable by the processor to:
detect a bottleneck among the plurality of touchpoints, wherein the text is generated based on the detected bottleneck.

15. The non-transitory computer readable medium of claim 10, wherein the code further comprises instructions executable by the processor to:
modify a parameter value associated with a touchpoint of the plurality of touchpoints;
repeat the simulation based on the modified parameter value; and
perform a sensitivity analysis based on the simulation and the repeated simulation, wherein the text is based on the sensitivity analysis.

16. The non-transitory computer readable medium of claim 10, wherein the code further comprises instructions executable by the processor to:
identify a plurality of parameter values for a touchpoint of the plurality of touchpoints;
repeat the simulation for each of the plurality of parameter values; and
select a recommended parameter value from the plurality of parameter values based on the repeated simulation, wherein the text is based on the recommended parameter value.

17. An apparatus comprising:
at least one processor;
at least one memory including instructions executable by the at least one processor;
the apparatus further comprising an agent generator component configured to generate a simulation agent including a plurality of attributes;
a machine learning model configured to generate a probability score for the simulation agent based on the plurality of attributes; and
a simulator component configured to perform a simulation of a user journey based on the probability score.

18. The apparatus of claim 17, wherein:
the agent generator component generates a plurality of simulation agents.

19. The apparatus of claim 17, further comprising:
a bottleneck detection component configured to detect a bottleneck among a plurality of touchpoints included in the user journey.

20. The apparatus of claim 17, further comprising:
a journey optimizer component configured to repeat the simulation for each of a plurality of parameter values for each of a plurality of touchpoints included in the user journey, and to select a recommended parameter value from the plurality of parameter values based on the repeated simulation.
